(19) United States
(12) Patent Application Publication
(10) Pub. No.: US 2021/0174890 A1
(43) Pub. Date: Jun. 10, 2021

(54) TEST CIRCUIT AND MEMORY CHIP USING TEST CIRCUIT

(71) Applicant: CHANGXIN MEMORY TECHNOLOGIES, INC., Hefei (CN)

(72) Inventors: Jia WANG, Hefei (CN); Liang ZHANG, Hefei (CN); Hongwen LI, Hefei (CN)

(21) Appl. No.: 17/182,242

(22) Filed: Feb. 23, 2021

Related U.S. Application Data
(63) Continuation of application No. PCT/CN2020/095339, filed on Jun. 10, 2020.

(30) Foreign Application Priority Data
Oct. 16, 2019 (CN) 201910981722.2

(51) Int. Cl. G11C 29/40; G11C 29/34

(52) U.S. Cl. CPC G11C 29/40; G11C 29/34

(57) ABSTRACT

Embodiments provide a test circuit and a memory chip. The test circuit is configured to read compressed data of a memory. The test circuit includes M storage blocks, wherein the M is an even number greater than or equal to 2. N storage blocks constitute one storage group, wherein the N is an even number greater than or equal to 2 and less than or equal to the M, and the M is an integral multiple of the N. The test circuit further includes a compressed data reading unit. One compressed data reading unit corresponds to one storage group. The compressed data reading unit is connected to the N storage blocks in the corresponding storage group. The compressed data reading unit receives a compressed data reading command and address information, and reads data in the N storage blocks according to the compressed data reading command and the address information.

### CROSS REFERENCE

This application is a continuation of PCT/CN2020/095339, filed on Jun. 10, 2020, which claims priority to Chinese Patent Application No. 201910981722.2, titled “TEST CIRCUIT AND MEMORY CHIP USING TEST CIRCUIT” and filed on Oct. 16, 2019, the entire contents of which are incorporated herein by reference.

### TECHNICAL FIELD

The present disclosure relates to the field of integrated circuit, and more particularly, to a test circuit and a memory chip using the test circuit.

### BACKGROUND

For DRAM chips, an array of chips may have manufacturing defects, so during a test phase, engineers need to find every defect in the array to ensure that all the defects are repaired.

Taking an LPDDR4 as an example, generally two test circuits are employed to find the defects in the array. One test circuit is an all-bank compression read architecture. Its advantage is that the time required to test a single DRAM chip is short, but its disadvantage is that a die size needs to be increased to store a compressed data reading circuit and 128 Lbus signal lines (signal lines specially configured to transmit compressed data), and four test data output ports are needed. Another test circuit is a one-bank compression read architecture, its advantage is to use its own Gbus signal line (a signal line configured to transmit normal data of a DRAM storage array, and also configured to transmit compressed data during a compressed data reading test) to complete the function of reading the compressed data, having no need to increase the die size, and only needing one test data output port. Its disadvantage is that long time is required to test the single DRAM chip.

Therefore, a new type of test circuit is urgently needed to overcome the above defects to meet the test requirements.

### SUMMARY

A technical problem to be solved by the present disclosure is to provide a test circuit and a memory chip using the test circuit, which can significantly reduce test time while not additionally increasing a size of the memory chip.

To solve the above problem, the present disclosure provides a test circuit for reading compressed data of a memory. The test circuit comprises M storage blocks divided into multiple storage groups, wherein M is an even number ≥2; a given one of the storage groups comprises N storage blocks, N being an even number and 2≤N≤M, M being an integral multiple of N; The test circuit further comprises compressed data reading units, wherein a given one of the compressed data reading units corresponds to one of the storage groups; The compressed data reading unit is connected to the N storage blocks of the corresponding storage group, the given compressed data reading unit is configured to receive a compressed data reading command and an address information, and to read data in the N storage blocks of the corresponding storage group according to the compressed data reading command and the address information.

Further, the M storage blocks are distributed in at least one odd-numbered column and at least one even-numbered column. At least one storage block in the odd-numbered column and at least one storage block in the even-numbered column constituting the given storage group.

Further, the test circuit also includes a test data output port connected to the given compressed data reading unit through a compressed data bus.

Further, one test data output port is connected to at least two compressed data reading units through the compressed data bus.

Further, the number of the test data output ports is two, one of test data output port is connected to four of compressed data reading units through the compressed data bus.

Further, the compressed data bus is an eight-bit bus.

Further, the M is 32 and the N is 4.

Further, the 32 storage blocks are distributed in eight rows and four columns. The four columns include an odd-numbered column I, an even-numbered column I, an odd-numbered column II, and an even-numbered column II. Four storage blocks included in one storage group are distributed in two rows and two columns. The two columns include a combination of the odd-numbered column I and the even-numbered column I or a combination of the odd-numbered column II and the even-numbered column II. Four compressed data reading units in total are provided between the odd-numbered column I and the even-numbered column I, and four compressed data reading units in total are provided between the odd-numbered column II and the even-numbered column II.

Further, the four compressed data reading units between the odd-numbered column I and the even-numbered column I are connected to a first test data output port by a first eight-bit compressed data bus, and the second set of four compressed data reading units between the odd-numbered column II and the even-numbered column II are connected to a second test data output port by a second eight-bit compressed data bus.

The present disclosure also provides a memory chip, which includes a data read-write bus, and further includes the aforementioned test circuit. The compressed data reading unit is arranged below the data read-write bus on the memory chip.

Further, the data read-write bus occupies a preset chip area I in the memory chip, and the compressed data reading unit occupies a preset chip area II in the memory chip. The compressed data reading unit is arranged below the data read-write bus on the memory chip, and the preset area II is smaller than the preset area I.

Further, a projection of the compressed data reading unit on a chip substrate is covered by a projection of the data read-write bus on the chip substrate.

In the test circuit provided by the present disclosure, one compressed data reading unit corresponds to a plurality of storage blocks, which can significantly reduce test time while not additionally increase a size of the memory chip.

### BRIEF DESCRIPTION OF THE DRAWINGS

FIG. 1 is a schematic structural diagram of a test circuit according to a first embodiment of the present disclosure.

FIG. 2 is a schematic structural diagram of the test circuit according to a second embodiment of the present disclosure.

FIG. 3 is a timing drive diagram of the test circuit according to the second embodiment of the present disclosure.

FIG. 4 is a schematic diagram of the test circuit according to a second embodiment of the present disclosure.

### DETAILED DESCRIPTION

Embodiments of a test circuit and a memory chip using the test circuit provided by the present disclosure are described below in detail with reference to the accompanying drawings.

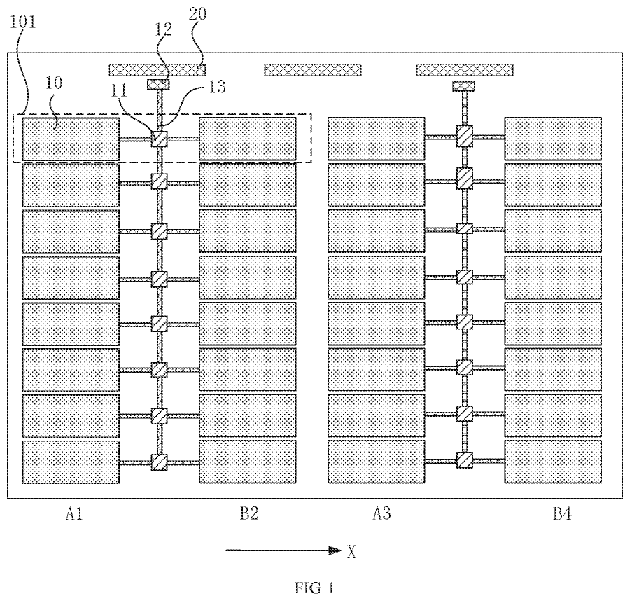

The test circuit provided by the present disclosure is configured to read compressed data of a memory. FIG. 1 is a schematic structural diagram of the test circuit according to a first embodiment of the present disclosure. With reference to FIG. 1, the test circuit includes M storage blocks 10, wherein the M is an even number greater than or equal to 2. In this embodiment, the M is equal to 32. That is, the test circuit includes 32 storage blocks 10. In other embodiments of the present disclosure, the number of the storage blocks 10 may be other values. N storage blocks 10 constitute one storage group 101, wherein the N is an even number greater than or equal to 2 and less than or equal to the M, and the M is an integral multiple of the N.

Further, the M storage blocks 10 may be distributed in at least one odd-numbered column and at least one even-numbered column. With reference to FIG. 1, in this embodiment, the M storage blocks 10 are distributed in two odd-numbered columns and two even-numbered columns. The M storage blocks 10 are distributed in an odd-numbered column I A1, an odd-numbered column II A3, an even-numbered column I B2, and an even-numbered column II B4. The odd-numbered columns and the even-numbered columns are alternately distributed. That is, the arrangement of the columns formed by the storage blocks 10 is sequentially as below: the odd-numbered column I A1, the even-numbered column I B2, the odd-numbered column II A3, and the even-numbered column II B4. It is to be understood that in other embodiments of the present disclosure, the M storage blocks 10 may also form other numbers of odd-numbered columns and even-numbered columns, respectively.

At least one storage block 10 in the odd-numbered column and at least one storage block 10 in the even-numbered column constitute the storage group 101. In this embodiment, the N is equal to 2. That is, one storage block 10 in the odd-numbered column and one storage block 10 in the even-numbered column constitute the storage group 101. In one embodiment, to facilitate the arrangement of the test circuit, two storage blocks 10 in the storage group 101 are arranged adjacently. As shown in FIG. 1, two storage blocks 10 adjacent in a horizontal direction (X direction) constitute the storage group 101. In other embodiments of the present disclosure, the N may also be other numerical values, as long as the M is an integral multiple of the N.

The test circuit also includes a compressed data reading unit 11. One compressed data reading unit 11 corresponds to one storage group 101. That is, the number of the compressed data reading units 11 is equal to that of the storage groups 101. In this embodiment, the storage blocks are divided into 16 storage groups, and the number of the compressed data reading units 11 is 16.

The compressed data reading unit 11 is connected to the N storage blocks 10 in the corresponding storage group 101. In this embodiment, the compressed data reading unit 11 is respectively connected to one storage block 10 in the odd-numbered column and one storage block 10 in the even-numbered column.

The compressed data reading unit 11 receives a compressed data reading command and address information, and reads data in the N storage blocks 10 according to the compressed data reading command and the address information. The compressed data reading command and the address information may be sent out by a control module of the memory. The address information is configured for providing an address of the storage block 10 read to the compressed data reading unit 11, such that the compressed data reading unit 11 performs a reading operation on the corresponding storage block according to the address information. In one embodiment, if the address information corresponds to the address of the first storage block 10 in the odd-numbered column I A1, the compressed data reading unit 11 performs the reading operation on the first storage block 10 in the odd-numbered column I A1. If the address information corresponds to the address of the first storage block 10 in the even-numbered column I B2, the compressed data reading unit 11 performs the reading operation on the first storage block 10 in the even-numbered column I B2.

In the test circuit provided by the present disclosure, one compressed data reading unit corresponds to at least two storage blocks. Compared with the existing technologies, the test circuit provided by the present disclosure can significantly reduce test time while not additionally increase a size of the memory chip.

Further, the test circuit also includes a test data output port 12. The test data output port 12 is connected to the compressed data reading unit 11 through a compressed data bus 13. Data read by the compressed data reading unit 11 is transmitted through the compressed data bus 13 to the test data output port 12 for data collection and analysis. The compressed data bus 13 is an eight-bit bus.

Further, the memory has a plurality of data input/output ports 20. In other embodiments of the present disclosure, the test circuit may use the data input/output port 20 of the memory as the test data output port 12 to save wiring space and improve an integration level.

Further, one test data output port 12 is connected to at least two compressed data reading units 11 through the compressed data bus 13. In this embodiment, the number of the test data output ports 12 is two, and one test data output port 12 is connected to eight compressed data reading units 11 through the compressed data bus 13. In one embodiment, the eight compressed data reading units 11 corresponding to the odd-numbered column I A1 and the even-numbered column I B2 share the same test data output port 12, and the eight compressed data reading units 11 corresponding to the odd-numbered column II A3 and the even-numbered column II B4 share the same test data output port 12.

The present disclosure also provides a second embodiment of the test circuit. The difference between the second embodiment and the first embodiment lies in that the number of the storage blocks contained in the storage group and the number of the compressed data reading units are different.

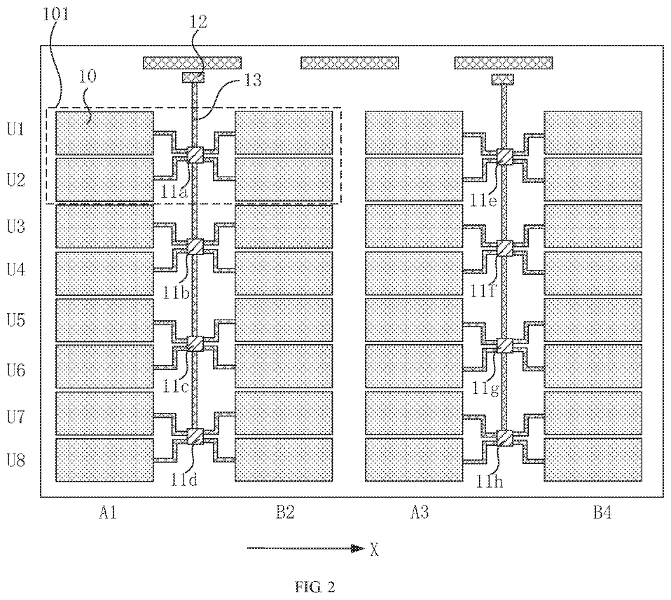

FIG. 2 is a schematic structural diagram of the test circuit according to the second embodiment of the present disclosure. With reference to FIG. 2, in this second embodiment, the M is equal to 32. That is, the test circuit includes 32 storage blocks 10. The N is equal to 4. That is, the 4 storage blocks 10 constitute the storage group 101.

In one embodiment, in the second embodiment, the 32 storage blocks are distributed in eight rows and four columns. The four columns include the odd-numbered column I A1, the even-numbered column I B2, the odd-numbered column II A3, and the even-numbered column II B4. The 4 storage blocks included in one storage group 101 are distributed in two rows and two columns, and the two columns include a combination of the odd-numbered column I A1 and the even-numbered column I B2 or a combination of the odd-numbered column II A3 and the even-numbered column II B4. The two rows are two adjacent rows. For example, the four storage blocks are distributed in the first row U1 and the second row U2, or the third row U3 and the fourth row U 4, or the fifth row U5 and the sixth row U6, or the seventh row U7 and the eighth row U8.

Four compressed data reading units 11 in total are provided between the odd-numbered column I A1 and the even-numbered column I B2, which are 11a, 11b, 11c, and 11d respectively. Four compressed data reading units 11 in total are provided between the odd-numbered column II A3 and the even-numbered column II B4, which are 11e, 11f, 11g, and 11h respectively. The compressed data reading unit 11a is connected to the storage blocks 10 in the first row U1 and the second row U2 of the odd-numbered column I A1 and the even-numbered column I B2. The compressed data reading unit 11b is connected to the storage blocks 10 in the third row U3 and the fourth row U4 of the odd-numbered column I A1 and the even-numbered column I B2. The compressed data reading unit 11c is connected to the storage blocks 10 in the fifth row U5 and the sixth row U6 of the odd-numbered column I A1 and the even-numbered column I B2. The compressed data reading unit 11d is connected to the storage blocks 10 in the seventh row U7 and the eighth row U8 of the odd-numbered column I A1 and the even-numbered column I B2. The compressed data reading unit 11e is connected to the storage blocks 10 in the first row U1 and the second row U2 of the odd-numbered column II A3 and the even-numbered column II B4. The compressed data reading unit 11f is connected to the storage blocks 10 in the third row U3 and the fourth row U4 of the odd-numbered column II A3 and the even-numbered column II B4. The compressed data reading unit 11g is connected to the storage blocks 10 in the fifth row U5 and the sixth row U6 of the odd-numbered column II A3 and the even-numbered column II B4. The compressed data reading unit 11h is connected to the storage blocks 10 in the seventh row U7 and the eighth row U8 of the odd-numbered column II A3 and the even-numbered column II B4.

Further, in the second embodiment of the present disclosure, the number of the test data output ports 12 is two, and one test data output port 12 is connected to the four compressed data reading units through the compressed data bus 13. That is, the compressed data reading units between the odd-numbered column I A1 and the even-numbered column I B2 are connected to the same test data output port 12 through the eight-bit compressed data bus 13. The compressed data reading units between the odd-numbered column II A3 and the even-numbered column II B4 are connected to the same test data output port 12 through the eight-bit compressed data bus 13.

A working method of the test circuit provided by the present disclosure is described below by taking the storage group 101 composed of the storage block A1-UI corresponding to the odd-numbered column I A1 and the first row U1, the storage block A1-U2 corresponding to the odd-numbered column I A1 and the second row U2, the storage block B2-UI corresponding to the even-numbered column I B2 and the first row U1 and the storage block B2-U2 corresponding to the even-numbered column I B2 and the second row U2 as an example. The compressed data reading unit 11a corresponding to the storage group 101 receives a compressed data reading command and address information, where the address information is an address of the storage block A1-UI. In this case, the compressed data reading unit 11a reads data in the storage block A1-UI, and the read data is transmitted to the test data output port 12 through the compressed data bus 13. The storage block A1-UI, the storage block A1-U2, the storage block B2-UI and the storage block B2-U2 belong to the same storage group 101. Therefore, after reading the data in the storage block A1-UI, the compressed data reading unit 11a may read, in sequence, the data in the storage block B2-UI, the data in the storage block A1-U2, and the data in the storage block B2-U2. These data may be transmitted, in sequence, to the test data output port 12 through the compressed data bus 13. After all the data of these storage blocks in the storage group 101 are read, data in the next storage group are read and transmitted.

In this embodiment, the compressed data reading units between the odd-numbered column I A1 and the even-numbered column I B2 and the compressed data reading units between the odd-numbered column II A3 and the even-numbered column II B4 are respectively connected to different test data output ports, such that they can read data simultaneously.

The above merely describes a working method of the test circuit. Other working methods may also be adopted without departing from the principle of the present disclosure. For example, data of the storage blocks in the odd-numbered columns in the storage group are first read, and then data of the storage blocks in the even-numbered columns in the storage group are read.

In the second embodiment of the present disclosure, the test circuit strikes a balance between the memory size, the test time and the number of the test data output ports 12. The test circuit provided by the present disclosure can significantly reduce the test time while not increase the memory size.

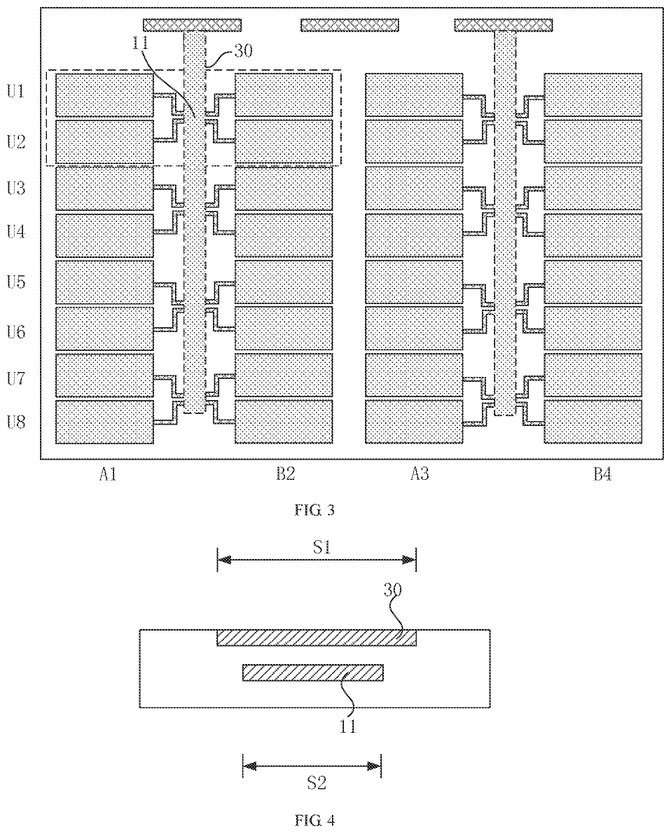

The present disclosure also provides a memory chip. The memory chip includes a data read-write bus and the above-mentioned test circuit. FIG. 3 is a schematic diagram of the data read-write bus and the test circuit in the memory chip. In FIG. 3, the data read-write bus is schematically drawn with broken lines. With reference to FIG. 3, in the memory chip, the compressed data reading unit 11 is arranged below the data read-write bus 30. FIG. 4 is a schematic diagram showing a relative position between the data read-write bus and the compressed data reading unit in a direction perpendicular to the memory chip. With reference to FIG. 4, in the direction perpendicular to the memory chip, the compressed data reading unit 11 is positioned below the data read-write bus 30.

In the structure of the memory chip, the data read-write bus inevitably occupies a certain chip region, while the data read-write bus is vacant and is not used. The memory chip of the present disclosure uses the region below the data read-write bus 30 to place the compressed data reading unit 11, such that the compressed data reading unit 11 is prevented from occupying extra space of the memory chip, thereby avoiding a problem of increasing the area of the memory chip due to the arrangement of the compressed data reading unit.

Further, with continued reference to FIG. 4, the data read-write bus 30 occupies a preset chip area I S1 in the memory chip, and the compressed data reading unit 11 occupies a preset chip area II S2 in the memory chip, wherein the preset area II S2 is smaller than the preset area I S1. Therefore, the compressed data reading unit can be further prevented from occupying the extra space of the memory chip.

Further, with continued reference to FIG. 4, a projection of the compressed data reading unit 11 on a chip substrate is covered by a projection of the data read-write bus 30 on the chip substrate. That is, the preset area II S2 of the compressed data reading unit 11 is completely within the range of the preset chip area I Si of the data read-write bus 30. The compressed data reading unit does not occupy at all a region beyond a vertical direction of the data read-write bus. Therefore, it is completely avoided the problem of increasing the size of the memory chip due to the arrangement of the compressed data reading unit.

What is claimed is:

1. A test circuit for reading compressed data of a memory, wherein the test circuit comprises M storage blocks divided into multiple storage groups, wherein M is an even number ≥2; a given one of the storage groups comprises N storage blocks, N being an even number and 2≤N≤M, M being an integral multiple of N;
wherein the test circuit further comprises compressed data reading units, wherein a given one of the compressed data reading units corresponds to one of the storage groups;
wherein the given compressed data reading unit is connected to the N storage blocks of the corresponding storage group, the given compressed data reading unit is configured to receive a compressed data reading command and an address information, and to read data in the N storage blocks of the corresponding storage group according to the compressed data reading command and the address information.

2. The test circuit according to claim 1, wherein the M storage blocks are distributed in at least one odd-numbered column and at least one even-numbered column, at least one storage block in the odd-numbered column and at least one storage block in the even-numbered column constituting the given storage group.

3. The test circuit according to claim 1, further comprising:
a test data output port connected to the given compressed data reading unit through a compressed data bus.

4. The test circuit according to claim 3, wherein one of the test data output port is connected to at least two of the compressed data reading units through the compressed data bus.

5. The test circuit according to claim 4, wherein number of the test data output ports is two, one of the test data output port being connected to four of the compressed data reading units through the compressed data bus.

6. The test circuit according to claim 3, wherein the compressed data bus is an eight-bit bus.

7. The test circuit according to claim 3, wherein M is 32, and N is 4.

8. The test circuit according to claim 7, wherein the 32 storage blocks are distributed in eight rows and four columns, wherein the four columns comprise an odd-numbered column I, an even-numbered column I, an odd-numbered column II, and an even-numbered column II;
wherein the four storage blocks comprised in the given storage group are distributed in two rows and two columns, wherein the two columns comprise a combination of the odd-numbered column I and the even-numbered column I, or a combination of the odd-numbered column II and the even-numbered column II;
wherein a first set of four compressed data reading units are provided between the odd-numbered column I and the even-numbered column I; and
wherein a second set of four compressed data reading units are provided between the odd-numbered column II and the even-numbered column II.

9. The test circuit according to claim 8, wherein the first set of four compressed data reading units between the odd-numbered column I and the even-numbered column I are connected to a first test data output port by a first eight-bit compressed data bus, and the second set of four compressed data reading units between the odd-numbered column II and the even-numbered column II are connected to a second test data output port by a second eight-bit compressed data bus.

10. A memory chip, comprising a data read-write bus and a test circuit, wherein the test circuit comprises M storage blocks divided into multiple storage groups, wherein M is an even number ≥2; a given one of the storage groups comprises N storage blocks, N being an even number and 2≤N≤M, M being an integral multiple of N;
wherein the test circuit further comprises compressed data reading units, wherein a given one of the compressed data reading units corresponds to one of the storage groups;
wherein the given compressed data reading unit is connected to the N storage blocks of the corresponding storage group, the given compressed data reading unit is configured to receive a compressed data reading command and an address information, and to read data in the N storage blocks of the corresponding storage group according to the compressed data reading command and the address information;
wherein the compressed data reading unit is arranged below the data read-write bus on the memory chip.

11. The memory chip according to claim 10, wherein the M storage blocks are distributed in at least one odd-numbered column and at least one even-numbered column, at least one storage block in the odd-numbered column and at least one storage block in the even-numbered column constituting the given storage group.

12. The memory chip according to claim 10, further comprising:
a test data output port connected to the given compressed data reading unit through a compressed data bus.

13. The memory chip according to claim 10, wherein one of the test data output port is connected to at least two of the compressed data reading units through the compressed data bus.

14. The memory chip according to claim 10, wherein number of the test data output ports is two, one of the test data output port being connected to four of the compressed data reading units through the compressed data bus.

15. The memory chip according to claim 10, wherein the compressed data bus is an eight-bit bus.

16. The memory chip according to claim 10, wherein M is 32, and N is 4.

17. The memory chip according to claim 10, wherein the 32 storage blocks are distributed in eight rows and four columns, wherein the four columns comprise an odd-numbered column I, an even-numbered column I, an odd-numbered column II, and an even-numbered column II;
wherein the four storage blocks comprised in the given storage group are distributed in two rows and two columns, wherein the two columns comprise a combination of the odd-numbered column I and the even-numbered column I, or a combination of the odd-numbered column II and the even-numbered column II;
wherein a first set of four compressed data reading units are provided between the odd-numbered column I and the even-numbered column I; and
wherein a second set of four compressed data reading units are provided between the odd-numbered column II and the even-numbered column II.

18. The memory chip according to claim 10, wherein the first set of four compressed data reading units between the odd-numbered column I and the even-numbered column I are connected to a first test data output port by a first eight-bit compressed data bus, and the second set of four compressed data reading units between the odd-numbered column II and the even-numbered column II are connected to a second test data output port by a second eight-bit compressed data bus.

19. The memory chip according to claim 10, wherein the data read-write bus occupies a preset chip area I in the memory chip, and the compressed data reading unit occupies a preset chip area II in the memory chip, wherein the preset area II is smaller than the preset area I.

20. The memory chip according to claim 10, wherein a projection of the compressed data reading unit on a chip substrate is covered by a projection of the data read-write bus on the chip substrate.
